(19) United States
(12) Patent Application Publication
(10) Pub. No.: US 2009/0253234 A1
(43) Pub. Date: Oct. 8, 2009

(54) METHODS OF FABRICATING LATERAL DMOS TRANSISTORS INCLUDING RETROGRADE REGIONS THEREIN

(76) Inventor: Mueng-ryul Lee, Seoul (KR)

Correspondence Address: MYERS BIGEL SIBLEY & SAJOVEC, PO BOX 37428, RALEIGH, NC, 27627, US

(21) Appl. No.: 12/483,682

(22) Filed: Jun. 12, 2009

Related U.S. Application Data
(62) Division of application No. 11/551,004, filed on Oct. 19, 2006.

(30) Foreign Application Priority Data
Oct. 25, 2005 (KR) 10-2005-0100892

(51) Int. Cl. H01L 21/8234; H01L 21/762

(52) U.S. Cl. 438/151; 438/197; 257/E21.561; 257/E21.616; 438/517

(57) ABSTRACT

A metal-oxide semiconductor transistor includes a semiconductor substrate including a source region and a drain region adjacent a surface of the substrate and a drift region between the source region and the drain region. The drift region has an impurity concentration distribution such that a peak impurity concentration of the drift region is displaced from the surface of the substrate. The peak impurity concentration of the drift region may be provided in a retrograde region in the drift region below the surface of the substrate and separated therefrom by a predetermined distance. Related methods of fabrication are also discussed.

### CROSS-REFERENCE TO RELATED PATENT APPLICATION

The present application is a Divisional Application of U.S. patent application Ser. No. 11/551,004, filed in the United States Patent Office on Oct. 19, 2006, which claims priority from Korean Patent Application No. 10-2005-0100892, filed on Oct. 25, 2005, in the Korean Intellectual Property Office, the respective disclosures of which are incorporated by reference herein in their entireties.

### FIELD OF THE INVENTION

The present invention relates to semiconductor devices, and more particularly, to Metal Oxide Semiconductor (MOS) devices and methods of fabricating the same.

### BACKGROUND OF THE INVENTION

High-power MOS Field Effect Transistors (hereinafter referred to as “MOSFETs”) may have a relatively high input impedance as compared with bipolar transistors, which may result in a relatively high power gain. Furthermore, as MOSFETs may be unipolar devices, they may have little time delay due to accumulation and/or reunion of minority carriers when the devices are turned off. Accordingly, MOSFETs may be widely used in switching mode power supplies, lamp ballasts, and/or motor driving circuits. A Double Diffused MOSFET structure formed using planar diffusion techniques may be used to provide such high power MOSFETs. For example, U.S. Pat. Nos. 5,059,547 and 5,378,912 disclose structures of conventional Lateral Double-Diffused Metal Oxide Semiconductor (LDMOS) transistors.

FIG. 1 is a cross-sectional view illustrating a conventional LDMOS transistor on a Semiconductor On Insulator (SOI) substrate. Referring now to FIG. 1, a buried oxide layer 103 (for use as a buried insulating layer) is formed on an upper surface of a P-type semiconductor substrate 101. An N-type drift region 105 and a P-type body region 107 are formed on an upper surface of the buried oxide layer 103 to provide an active region. A drain region 109 doped with N⁺ type impurity ions is formed in the N-type drift region 105, and a source region 113 doped with N⁺ type impurity ions is formed in the P-type body region 107. A P⁺ type source contact region 111 is formed adjacent to the source region 113. Also, a gate electrode 115 is formed on the semiconductor substrate 101 on a gate insulating layer 117. A field insulating layer 119, which may be used to improve device breakdown voltage, is formed on a surface of the drift region 105. A channel region may be formed at a surface portion of the body region 107 between the source region 113 and a contact surface where the body region 107 meets the drift region 105 upon application of an appropriate voltage to the gate electrode 115.

FIG. 2 is a graph illustrating the concentration distribution of the N⁺ type impurity ions implanted in the drift region 105 of the conventional LDMOS transistor illustrated in FIG. 1.

Referring again to FIG. 1, the drift region 105 is formed by implanting impurity ions, such as phosphorous ions, into a surface of the semiconductor substrate 101 where the drift region 105 will be formed, and diffusing the impurity ions at a relatively high temperature for a period of time. This diffusion process may be relatively lengthy, and may allow the phosphorous ions on the surface of the semiconductor substrate 101 to diffuse under the surface into a bulk region. A concentration of the impurity ions may be highest adjacent to the field oxide layer at the surface of the semiconductor substrate 101. As such, the impurity concentration distribution may follow a Gaussian distribution, as shown in FIG. 2.

Thus, when a sufficient bias voltage is applied to the gate electrode 115 and the drain region 109, the resistance may be relatively low adjacent the surface of the semiconductor substrate 101, but may be relatively high in the bulk region. Accordingly, most of the current may flow between the source 113 and the drain 109 regions through the surface of the semiconductor substrate 101. As such, an electric field may be concentrated around a sidewall of the N⁺ drain region 109. For relatively small amounts of current, this may present relatively few problems. However, for larger amounts of current at the sidewall portions, holes and electrons may be increased due to impact ionization, which may deteriorate the breakdown voltage of the device.

Accordingly, when a relatively high bias voltage is supplied to the gate electrode 115 to increase saturation current in a conventional LDMOS transistor, the breakdown voltage may be decreased, which may worsen a Safe Operating Area (SOA) characteristic of the device. A length of the drift region 105 may be increased to improve the SOA characteristic; however, this may increase the physical dimensions of the device.

### SUMMARY OF THE INVENTION

Some embodiments of the present invention may provide Lateral Double-Diffused Metal Oxide Semiconductor (LDMOS) transistors that include enhanced current characteristics and/or breakdown characteristics as well as a Safe Operating Area (SOA) characteristics.

Some embodiments of the present invention may also provide methods of fabricating LDMOS transistors having enhanced current characteristics, breakdown characteristics, and/or SOA characteristics.

According to some embodiments of the present invention, an LDMOS transistor may include a drift region between a channel region and a drain region formed within a semiconductor substrate. The drift region may have a retrograde region with an impurity ion density greater than that of the surface of the semiconductor substrate.

A density profile of the impurity ions in the drift region may decrease from the surface of the semiconductor substrate and may increase to have a peak value in the retrograde region. The retrograde region may be formed below a bottom of the drain region in a vertical direction. Also, the retrograde region may extend to the bottom of the drain region in the lateral direction, and a point/location of corresponding the peak impurity concentration in the retrograde region may be located within a range of about 1-3 μm from an upper surface of the semiconductor substrate.

According to other embodiments of the present invention, an LDMOS transistor may include a semiconductor substrate. A drift region of a first conductivity type formed under an upper surface of the semiconductor substrate may have a retrograde region with an impurity ion density greater than that in the surface of the semiconductor substrate. Also, a body region of a second conductivity type may form a contact plane with the drift region, and may be formed under the surface of the semiconductor substrate. A source region of the first conductivity type separated from the contact plane may be formed in the body region, and a drain region of the first conductivity type separated from the contact plane may be formed in the drift region. A channel region may be formed between the source region and the contact plane, and a gate electrode may be formed on the channel region.

In some embodiments, the semiconductor substrate may be an SOI (Semiconductor On Insulator) substrate including a buried insulating layer in a middle portion thereof. Also, the body region and the drift region may contact an upper surface of the buried insulating layer, and the retrograde region may be separated from and upper surface of the buried insulating layer. Furthermore, a field insulating layer may be formed in the upper surface of the semiconductor substrate within the drift region and between the drain region and the channel region, and the gate electrode may partially cover the field insulating layer. Also, the retrograde region may be separated from the body region.

According to still other embodiments of the present invention, a method of fabricating an LDMOS (Lateral Double-diffused Metal Oxide Semiconductor) transistor may include implanting impurity ions of a first conductivity type in a semiconductor substrate to form a drift region of the first conductivity type. Impurity ions of a second conductivity type may be implanted in a portion of the semiconductor substrate to form a body region of the second conductivity type, which may form a contact plane with the drift region. Impurity ions of the first conductivity type may be implanted within the drift region to form a retrograde region having an impurity ion density greater than that in a surface of the semiconductor substrate. After forming a gate electrode on the semiconductor substrate, a source region of the first conductivity type separated from the contact plane within the body region may be formed to correspond to the gate electrode. A drain region of the first conductivity type separated from the contact plane may be formed within the drift region.

The retrograde region may be formed using an ion implantation energy of about 2000-7000 KeV, and an implantation dose of about 5×10¹¹ to about 2×10¹² ions/cm². The first conductive type of the impurity ions may be P-type and the second conductivity type may be N-type, or vice versa. The retrograde region may be a buried impurity region within the drift region having a peak density profile at a predetermined depth. The LDMOS transistor may further include an insulating pattern on upper surfaces of the semiconductor substrate of both sides of the drain region to prevent the concentration of an electric field.

According to further embodiments of the present invention, a metal-oxide semiconductor (MOS) transistor includes a semiconductor substrate including a source region and a drain region adjacent a surface of the substrate and a drift region between the source region and the drain region. The drift region has an impurity concentration distribution such that a peak impurity concentration of the drift region is displaced from the surface of the substrate.

In some embodiments, the drift region may be a retrograde region below the surface of the substrate and separated therefrom by a predetermined distance. The peak impurity concentration of the drift region may be provided in a portion of the retrograde region. For example, an impurity concentration of the drift region may decrease between a portion of the drift region adjacent the surface of the substrate and the retrograde region. In addition, an impurity concentration of the drift region may decrease between the retrograde region and a surface of the substrate opposite the source and drain regions.

In other embodiments, the retrograde region may laterally extend at the predetermined distance below the surface of the substrate and under the drain region. Also, an edge of the retrograde region may be aligned with an edge of the drain region.

In some embodiments, the semiconductor substrate may further include a body region adjacent the surface of the substrate between the drift region and the source region. The source region, the drain region, and the drift region may be a first conductivity type, and the body region may be a second conductivity type. In addition, the retrograde region may be separated from the body region.

In other embodiments, the transistor may include a field insulating layer on the surface of the substrate adjacent the drift region and between the source region and the drain region. The retrograde region may laterally extend at the predetermined distance below the surface of the substrate and under the drain region and the field insulating layer. The transistor may further include a gate insulating layer on the surface of the substrate adjacent the drift region and between the source region and the drain region, and a gate electrode on the gate insulating layer.

According to still further embodiments of the present invention, a metal-oxide semiconductor (MOS) transistor includes a semiconductor substrate, a source region of a first conductivity type adjacent a surface of the substrate, and a drain region of the first conductivity type adjacent the surface of the substrate. A drift region of the first conductivity type is provided in the substrate between the source region and the drain region. The drift region includes a retrograde region therein below the surface of the substrate. The retrograde region has an impurity concentration greater than an impurity concentration of a portion of the drift region adjacent the surface of the substrate. A body region of a second conductivity type is provided in the substrate adjacent the surface thereof between the drift region and the source region, and is configured to provide a channel region between the source region and the drift region. A gate electrode is provided on the channel region.

According to other embodiments of the present invention, a metal-oxide semiconductor (MOS) transistor includes a semiconductor substrate including a source region and a drain region adjacent a surface of the substrate and a drift region between the source region and the drain region. The drift region includes a retrograde region below the surface of the substrate. The retrograde region has an impurity concentration distribution such that an impurity concentration of the retrograde region increases relative to that of adjacent portions of the drift region.

According to still other embodiments of the present invention, a method of forming a metal-oxide semiconductor (MOS) transistor includes forming a source region and a drain region in a semiconductor substrate adjacent a surface thereof, and forming a drift region in the semiconductor substrate. The drift region has an impurity concentration distribution such that a peak impurity concentration of the drift region is displaced from the surface of the substrate.

In some embodiments, forming the drift region may include forming a retrograde region below the surface of the substrate and separated therefrom by a predetermined distance. The retrograde region may have an impurity concentration greater than an impurity concentration of a portion of the drift region adjacent the surface of the substrate. The peak impurity concentration of the drift region may be provided in a portion of the retrograde region. For example, an impurity concentration of the drift region may decrease between a portion of the drift region adjacent the surface of the substrate and the retrograde region. Also, an impurity concentration of the drift region may decrease between the retrograde region and a surface of the substrate opposite the source and drain regions.

In other embodiments, a body region may be formed adjacent the drift region and adjacent the surface of the substrate. For example, the drift region may be a first conductivity type, and the body region may be formed by implanting impurity ions of second conductivity type into the substrate. The retrograde region may be formed to be separated from the body region.

In some embodiments, to form the drift region, impurity ions of a first conductivity type may be implanted into the substrate at a first implantation energy to provide an initial impurity concentration distribution. The initial impurity concentration distribution may have a peak impurity concentration adjacent the surface of the substrate. Impurity ions of the first conductivity type may be implanted into the substrate at a second implantation energy greater than the first implantation energy to provide the impurity concentration distribution having the peak impurity concentration displaced from the surface of the substrate. For example, the impurity ions may be implanted at the second implantation energy at a dose of about 5×10¹¹ ions/cm² to about 2×10¹² ions/cm². Also, the impurity ions may be implanted using an implantation energy of about 2000 keV to about 7000 keV.

Thus, according to some embodiments of the present invention, by forming the retrograde region having a high density and buried within the drift region, the current characteristics, breakdown voltage characteristics, and/or SOA characteristics may be improved.

### BRIEF DESCRIPTION OF THE DRAWINGS

FIG. 1 is a cross-sectional view of a conventional LDMOS transistor;

FIG. 2 is a graph illustrating a density profile of a drift region of the conventional LDMOS transistor illustrated in FIG. 1;

FIG. 3 is a sectional view of an LDMOS transistor according to some embodiments of the present invention;

FIG. 4 is a graph illustrating a density profile of a drift region of the LDMOS transistor of FIG. 3 according to some embodiment of the present invention;

FIGS. 5 through 9 are cross-sectional views illustrating methods of fabricating an LDMOS transistor according to some embodiments of the present invention; and

FIG. 10 is a graph illustrating Id-Vd characteristics of conventional LDMOS transistors and LDMOS transistors according some embodiments of the present invention.

### DETAILED DESCRIPTION OF EMBODIMENTS OF THE INVENTION

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element or layer is referred to as being “on”, “adjacent”, “connected to”, or “coupled to” another element or layer, it can be directly on, adjacent, connected or coupled to the other element or layer or intervening elements or layers may be present. In contrast, when an element is referred to as being “directly on”, “directly adjacent”, “directly connected to”, or “directly coupled to” another element or layer, there are no intervening elements or layers present. It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

FIG. 3 is a cross-sectional view of an LDMOS transistor according to some embodiments of the present invention. The LDMOS transistor may be formed on a single-crystalline substrate or a Semiconductor on Insulator (SOI) substrate. As shown in FIG. 3, the LDMOS transistor is formed on an SOI substrate according to some embodiments of the present invention.

Referring now to FIG. 3, the LDMOS transistor includes a semiconductor substrate 301 of a second conductivity type (e.g., P type). Also, a buried insulating layer 303, such as a buried oxide layer, is provided on a surface of the semiconductor substrate 301. A drift region 305 of a first conductivity type (e.g., N-type) is provided on an upper surface of the buried insulating layer 303. For example, the drift region 305 may be implanted with phosphorous ions. A retrograde region 321 of the first conductivity type is formed within the drift region 305, and a drain region 309 is provided at a surface portion of the drift region 305. The retrograde region 321 may have an impurity concentration greater than an impurity concentration of a portion of the drift region 305 adjacent the surface of the substrate 301. A body region 307 of the second conductivity type is provided adjacent to the drift region 305 to provide a contact plane/region. An N⁺ source region 313 is provided within the body region 307, and a P⁺ source contact region 311 is provided adjacent to the N⁺ source region 313 within the body region 307. A gate electrode 315 is also provided on the semiconductor substrate 301 including a gate insulating layer 317 between the gate electrode 315 and the body region 307.

A channel region is provided at a surface of the body region 307 between the source region 313 and the contact plane where the body region 307 contacts the drift region 305 when an appropriate bias voltage is applied to the gate electrode 309. Furthermore, a field insulating layer 319, such as a field oxide layer, may be provided to contact a sidewall of the drain region 309 at a surface of the drift region 305 between the drain region 309 and the contact plane. The gate electrode 315 may partially cover the field insulating layer 319.

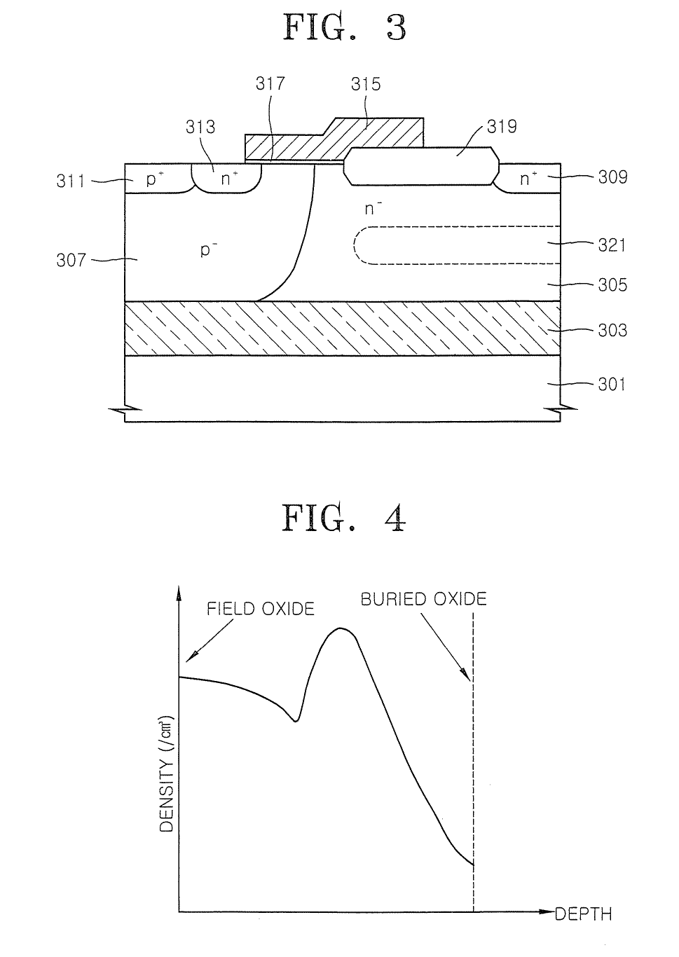

FIG. 4 is a graph illustrating the impurity concentration distribution of the drift region 305 between the field insulating layer 319 and the buried insulating layer 303 in the LDMOS transistor illustrated in FIG. 3. Referring now to FIG. 4, the concentration density gradually decreases from the surface of the drift region 305 adjacent to the field insulating layer 319 (e.g., a field oxide layer), increases to a peak value at a certain depth around the retrograde region 321, and decreases again toward the buried insulating layer 303 (e.g., a buried oxide layer).

The retrograde region 321 may include a predetermined length and/or be located at a predetermined depth from the surface of the drift region 305, for example, to provide a lower-resistance current flow path than at the surface of the drift region 305. According to the embodiments of the present invention, illustrated in FIG. 3, the retrograde region 321 may be provided in a portion of the drift region 305 located under and/or below the drain region 309 relative to the substrate 301. Also, one side of the retrograde region 321 may laterally extend to be aligned with an edge of the drain region 309. The other side of the retrograde region 321 may be disposed at a predetermined distance from the body region 307. For example, the drain region 309 may be about 0.5 μm thick, and the peak concentration (i.e., a point of maximum impurity concentration) of the retrograde region 321 may be formed at a depth of about 1-3 μm from the upper surface of the semiconductor substrate 301.

In the concentration distribution shown in FIG. 4 the impurity concentration of the drift region 305 may decrease from the surface of the semiconductor substrate 301 towards the lower portion of the drift region 305 because N-type impurity ions, such as phosphorous ions, may be implanted in the surface of the semiconductor substrate 301 and then diffused to form the drift region 305. Also, the retrograde region 321 may be ion implanted at an implantation energy sufficient to provide a peak impurity concentration at a predetermined depth from the surface of the semiconductor substrate 301. At impurity densities less than the peak value, other portions of the retrograde region 321 may also include impurity concentrations greater than the impurity concentration at the surface of the semiconductor substrate 301.

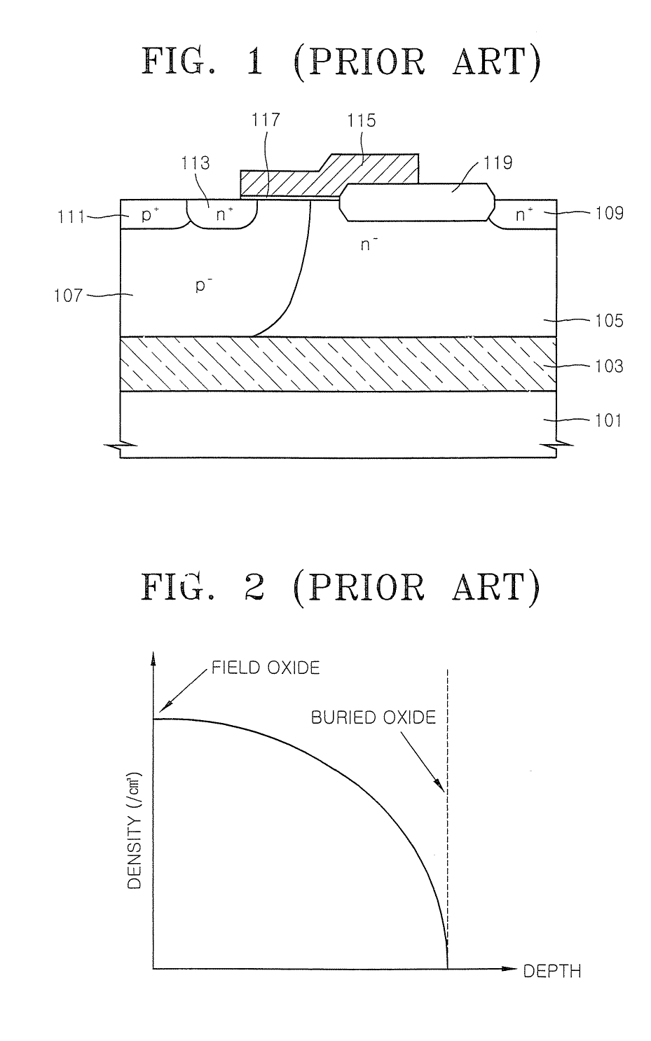

When comparing the concentration distribution profiles of some embodiments of the present invention as shown in FIG. 3 with that of a conventional N-type drift region as shown in FIG. 1, the current in the conventional device may generally flow from the source 113 to the drain 109 adjacent to a surface region of the drift region 105, while the current in the device of FIG. 3 may flow from the surface region of the drift region 305 to the higher impurity concentration retrograde region 321 at a predetermined depth from the surface of the drift region 305. As such, the concentration of the electric field applied at a junction of the drain region 309 and the surface of the drift region 305 may be dispersed to other portions of the drain region 309. More particularly, the electric field that may have been concentrated on one portion of a sidewall of the drain region 309 in a conventional device is distributed along the sidewall and a bottom of the drain region 309 due to the influence of the retrograde region 321 according to some embodiments of the present invention, which may thereby improve breakdown voltage characteristics. The electric field may be distributed because current tends to flow through regions with less resistance, such as the retrograde region 321.

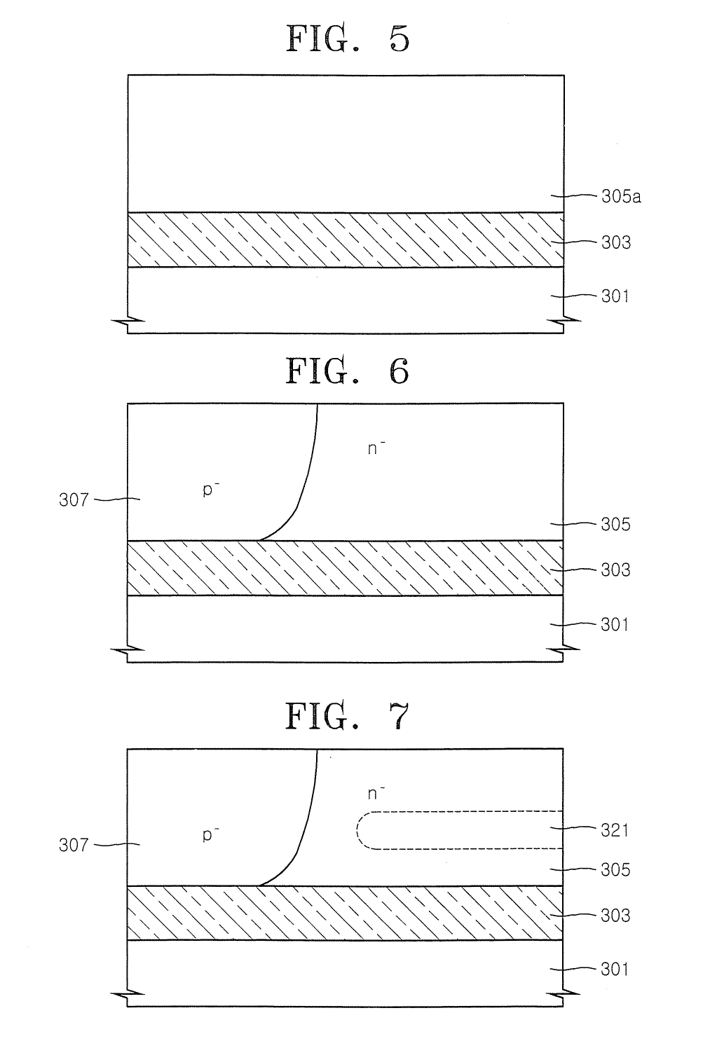

Methods of fabricating the LDMOS transistors according to some embodiments of the present invention will now be described with reference to FIGS. 5 through 9. Referring now to FIG. 5, a Silicon On Insulator (SOI) substrate includes a triple-layered structure in which a semiconductor layer 305a is composed of a single-crystalline silicon layer with an active region therein. The semiconductor layer 305a is formed on an upper surface of a buried insulating layer 303 composed of, for example, a buried oxide (BOX) layer, and is disposed on a semiconductor substrate 301 composed of, for example, silicon. The semiconductor layer 305a provides an active layer for a transistor. Such an active layer may be bonded by processing a typical wafer, or may be epitaxially grown. Other SOI techniques may also be used. A device fabricated using the SOI substrate having the foregoing structure may be characterized by relatively low substrate biasing effects and short channel effect control. In addition, the SOI substrate provides an isolated structure, as parasitic capacitance (such as junction capacitance and/or interconnect capacitance) may be reduced as compared with a conventional bulk silicon device. These characteristics may be effective in attaining low power consumption and high performance in integrated circuits/devices. In the embodiments of FIGS. 5 through 9, the active layer may be epitaxially grown.

Referring to FIG. 6, impurity ions are implanted in the semiconductor layer 305a to form a drift region 305 and a body region 307. More particularly, N-type impurity ions, such as phosphorous ions, may be implanted into the upper surface of the semiconductor layer 305a at a dose of about 2×10¹² ions/cm², and impurity diffusion may be performed at a predetermined temperature for a predetermined time, for example, at about 1100-1200° C. for about 7-9 hours, to form the drift region 305. The drift region 305 may be formed by diffusing the impurity ions to reach an upper surface of the buried insulating layer 303, so that the drift region 305 extends from the upper surface of the drift region 305 to an upper surface of the buried insulating layer 303. In addition, a predetermined ion implantation mask (not shown) may be used to selectively implant P-type impurity ions, such as boron (B) ions, at a predetermined dose quantity to form the body region 307 having a contact plane/junction with the drift region 305. The P-type body region 307 may partially act as a channel region of the LDMOS that will be described later.

Referring to FIG. 7, a retrograde region 321 is formed in a predetermined portion of the drift region 305. The retrograde region 321 may be formed by implanting phosphorous ions at, for example, a dose quantity of about 5×10¹¹ to about 2×10¹² ions/cm² and at an implantation energy of about 2000-7000 KeV, using an ion implantation mask (not shown) formed by photolithography. For example, in some embodiments, the ion implantation energy may be about 4000 to about 5000 KeV, and the dosing of the impurity ions may be about 1×10¹² ions/cm². The retrograde region 321 may be formed to have a depth of about 1-3 μm, using a location of a peak value of the impurity density as a reference. For example, the retrograde region 321 may be formed to have a depth of about 1-2 μm in a 100V class LDMOS device and/or about 2-3 μm in a 200V LDMOS device.

The retrograde region 321 may be provided to extend within the drift region 305. More particularly, the retrograde region 321 may have one end separated from the P-type body region 307 by a predetermined distance in a lateral direction, and may be disposed below a lower portion of a field insulating layer 319 (which will be formed in an upper surface of the drift region 305) by a predetermined distance. In addition, the other end of the retrograde region 301 may extend to be aligned with an edge of a drain region 309. As such, in the vertical direction, the retrograde region 321 may be disposed under a bottom portion of the drain region 309.

Referring to FIG. 8, the field insulating layer 319 (composed of, for example, a field oxide layer) is formed using a LOCal Oxidation of Silicon (LOCOS) technique. As illustrated in FIG. 8, the field insulating layer 319 may be formed in an upper surface of the drift region 305 and above the retrograde region 321, and may be separated from the body region 307 by a predetermined distance.

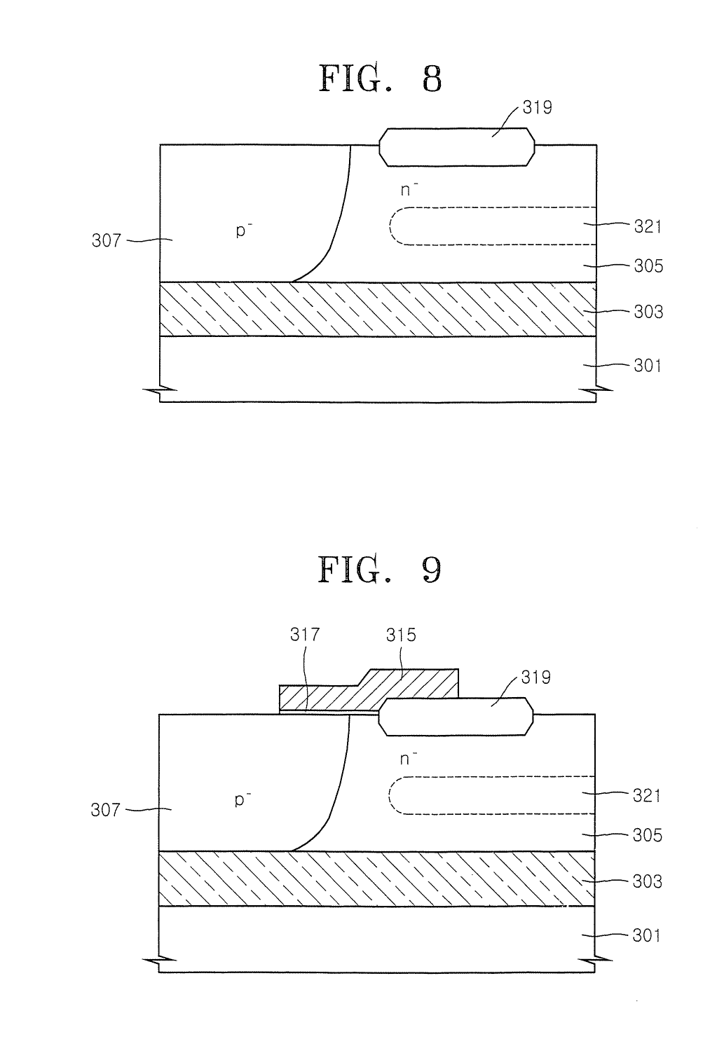

Referring to FIG. 9, a gate electrode 315 is formed. More particularly, a gate insulating material, such as silicon oxide, and a gate electrode material, such as polysilicon, may be deposited on a surface of the semiconductor substrate 301 where the field insulating layer 319 is formed, and photolithography may be used to form a gate pattern including a gate insulating layer 317 and the gate electrode 315. As shown in FIG. 9, a first end of the gate electrode 315 may extend onto a surface of the body region 307, and a second end may extend onto the field insulating layer 319.

Again referring to FIG. 3, N⁺ type impurity ions are implanted into the exposed portions of the body region 307 and the drift region 305 using the gate electrode 315 and the field insulating layer 319 as ion implanting masks, thereby forming the source region 313 and the drain region 309 to a predetermined depth of, for example, about 0.5 μm. The source contact region 311 may be formed by implanting P⁺ impurity ions adjacent to the source region 313. A channel region may be formed in the body region 307 between the source region 313 and the drift region 305 upon application of an appropriate voltage at the gate electrode 315.

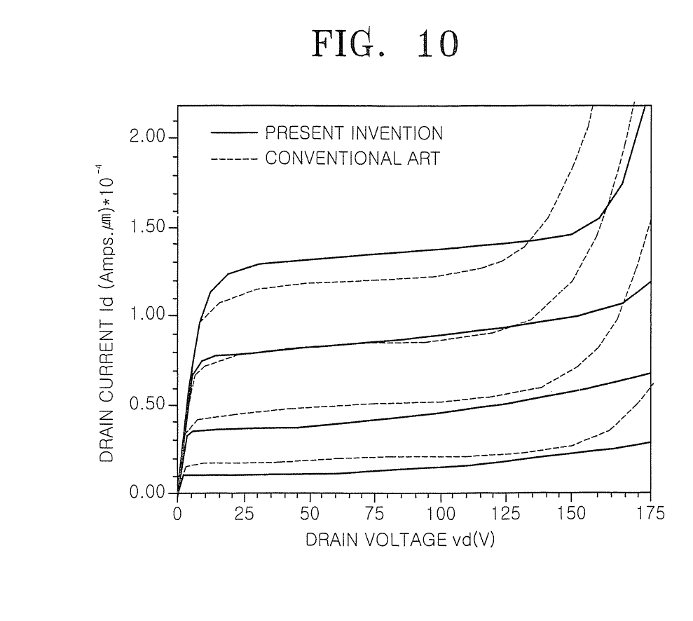

FIG. 10 is a graph illustrating drain voltage Vd versus drain current Id characteristics with respect to the LDMOS transistor according to some embodiments of the present invention illustrated in FIG. 3 and the conventional LDMOS transistor illustrated in FIG. 1. In FIG. 10, the dotted lines denote Vd-Id characteristics the conventional LDMOS transistor, and the solid lines denote the Vd-Id characteristics of the LDMOS transistor according to some embodiments of the present invention. The results were obtained at gate voltages of 2V, 3V, 4V, and 5V.

As shown in FIG. 10, the breakdown voltages BV of the conventional LDMOS transistor and the LDMOS transistor according to some embodiments of the present invention are both 200V. However, in the conventional LDMOS transistor, the on-breakdown voltage (on-BV) is less than about 180V when the gate voltage is higher than about 2V, and the on-breakdown voltage is decreased to about 135V when the gate voltage reaches about 5V. According to some embodiments of the present invention, the on-breakdown voltage is not decreased until the gate voltage reaches about 4V but is decreased to about 170V when the gate voltage is about 5V, which is considerably higher than the on-breakdown voltage (135V) of the conventional technique. Furthermore, a saturation current of the LDMOS transistor according to some embodiments of the present invention when the gate voltage is about 5V is greater than that of the conventional LDMOS transistor.

Thus, according to some embodiments of the present invention, a current flow path at the surface of a drift region in a LDMOS transistor may be distributed due to a high impurity density retrograde region formed within the drift region. As such, a current path between the source and drain regions may be displaced from the surface of the drift region adjacent the gate electrode. Accordingly, current characteristics and/or breakdown voltage characteristics of the LDMOS transistor may be enhanced, and SOA characteristics of the LDMOS transistor can be improved without increasing a length of the drift region.

While the present invention has been particularly shown and described with reference to exemplary embodiments thereof, it will be understood by those of ordinary skill in the art that various changes in form and details may be made therein without departing from the spirit and scope of the present invention as defined by the following claims.

That which is claimed:

1. A method of fabricating a metal-oxide semiconductor (MOS) transistor, the method comprising:
forming a source region and a drain region in a semiconductor substrate adjacent a surface thereof; and
forming a drift region in the semiconductor substrate having an impurity concentration distribution such that a peak impurity concentration of the drift region is displaced from the surface of the substrate,
wherein the forming the drift region comprises:
implanting impurity ions of a first conductivity type into the substrate at a first implantation energy to provide an initial impurity concentration distribution; and
implanting impurity ions of the first conductivity type into the substrate at a second implantation energy greater than the first implantation energy to provide the impurity concentration distribution having the peak impurity concentration displaced from the surface of the substrate.

2. The method of claim 1, wherein the initial impurity concentration distribution has a peak impurity concentration adjacent the surface of the substrate.

3. The method of claim 1, wherein implanting the impurity ions at the second implantation energy comprises:
implanting the impurity ions using an implantation energy of about 2000 keV to about 7000 keV.

4. The method of claim 1, wherein implanting the impurity ions at the second implantation energy comprises:
implanting the impurity ions at a dose of about 5×10¹¹ ions/cm² to about 2×10¹² ions/cm².

5. The method of claim 1, further comprising:
forming a gate insulating layer on the surface of the substrate adjacent the drift region and between the source region and the drain region; and
forming a gate electrode on the gate insulating layer.

6. The method of claim 1, further comprising:
forming a buried insulating layer; and
forming the semiconductor substrate on the buried insulating layer to define a semiconductor-on-insulator (SOI) substrate.

7. The method of claim 1, wherein forming the drift region comprises:
forming a retrograde region below the surface of the substrate and separated therefrom by a predetermined distance,
wherein the retrograde region has an impurity concentration greater than an impurity concentration of a portion of the drift region adjacent the surface of the substrate, and wherein the peak impurity concentration of the drift region is provided in a portion of the retrograde region.

8. The method of claim 7, wherein an impurity concentration of the drift region decreases between a portion of the drift region adjacent the surface of the substrate and the retrograde region.

9. The method of claim 7, wherein an impurity concentration of the drift region decreases between the retrograde region and a surface of the substrate opposite the source and drain regions.

10. The method of claim 7, wherein forming the retrograde region comprises:
forming the retrograde region so that the portion of the retrograde region having the peak impurity concentration is displaced from the surface of the substrate by a distance of about 1 micrometer (μm) to about 3 micrometers (μm).

11. The method of claim 7, wherein forming the retrograde region comprises:
forming the retrograde region to laterally extend at the predetermined distance below the surface of the substrate and under the drain region.

12. The method of claim 11, wherein forming the retrograde region further comprises:
forming the retrograde region such that an edge of the retrograde region is aligned with an edge of the drain region.

13. The method of claim 7, further comprising:
forming a field insulating layer on the surface of the substrate adjacent the drift region and between the source region and the drain region,
wherein the retrograde region laterally extends at the predetermined distance below the surface of the substrate and under the drain region and the field insulating layer.

14. The method of claim 7, further comprising:
forming a body region adjacent the drift region and adjacent the surface of the substrate,
wherein forming the retrograde region comprises forming the retrograde region separated from the body region.

15. The method of claim 14, wherein the drift region comprises a first conductivity type, and wherein forming the body region comprises:
implanting impurity ions of second conductivity type into the substrate.

16. A method of fabricating a metal-oxide semiconductor (MOS) transistor, the method comprising:
providing a semiconductor substrate on a buried insulating layer;
forming a drift region of a first conductivity type in the substrate and a body region of a second conductivity type in the substrate adjacent the drift region;
forming a retrograde region in the drift region below a surface of the substrate opposite the buried insulating layer, the retrograde region having an impurity concentration greater than that of portions of the drift region adjacent the buried insulating layer, and greater than that of portions of the drift region adjacent the surface of the substrate opposite the buried insulating layer;
forming a source region and a drain region of the first conductivity type in the surface of the substrate opposite the buried insulating layer, wherein the body region is configured to provide a channel region between the source region and the drift region; and
forming a gate electrode on the channel region.

17. A method of fabricating a metal-oxide semiconductor (MOS) transistor, the method comprising:
forming a source region and a drain region in a first surface of a semiconductor substrate; and
forming a drift region in the substrate including a retrograde region therein between the first surface of the substrate and a second surface of the substrate opposite the first surface, the retrograde region having an impurity concentration greater than that of portions of the drift region immediately adjacent the first surface of the substrate, and greater than that of portions of the drift region immediately adjacent the second surface of the substrate opposite the first surface.

18. The method of claim 17, wherein a peak impurity concentration of the drift region is provided in a portion of the retrograde region.

19. The method of claim 18, wherein an impurity concentration of the drift region decreases between the first surface of the substrate and the retrograde region.

20. The method of claim 19, wherein an impurity concentration of the drift region decreases between the retrograde region and the second surface of the substrate.
